(19) United States
(12) Patent Application Publication
(10) Pub. No.: US 2014/0278159 A1
(43) Pub. Date: Sep. 18, 2014

(54) Alternator Tester Having Belt Slip Detection

(71) Applicant: Bosch Automotive Service Solutions LLC, Warren, MI (US)

(72) Inventor: Manokar Chinnadurai, Owatonna, MN (US)

(21) Appl. No.: 14/206,690

(22) Filed: Mar. 12, 2014

Related U.S. Application Data
(60) Provisional application No. 61/791,438, filed on Mar. 15, 2013.

(51) Int. Cl. G01R 31/00

(52) U.S. Cl. CPC G01R 31/007
USPC 702/58

(57) ABSTRACT

A diagnostic tool for testing the performance of a component of a vehicle includes a processor configured to process test information from an alternator component of the vehicle and control and activate the alternator component. The diagnostic tool further includes a memory configured to store the test information of the alternator component and software that operates the alternator component of the vehicle, and a sensor configured to sense the output voltage of the alternator and ensure that the diagnostic tool is properly operating the alternator component.

### CROSS-REFERENCE TO RELATED APPLICATIONS

This application claims priority to U.S. patent application entitled, ALTERNATOR TESTER HAVING BELT SLIP DETECTION, filed Mar. 15, 2013, having a Ser. No. 61/791,438, the disclosure of which is hereby incorporated by reference in its entirety.

### FIELD OF THE DISCLOSURE

The disclosure pertains to the field of testing vehicle motor rotary accessory devices. More particularly, the disclosure relates to a device for the more accurate testing of the alternator of a motor vehicle engine or the like.

### BACKGROUND

It is well known in the vehicle industry to employ analytical tools in connection with the analysis of vehicle motors and their individual components and systems. One such engine component that is often analyzed is the alternator. Alternators are used in connection with an engine and are typically belt driven by the engine. Alternators have internal components, which when rotated supply electrical power to a vehicle and/or an engine. Alternators are typically removable but oftentimes rigidly mounted via a bracket to the engine block or the chassis of the vehicle.

It is often desirable to test alternators after removal from a vehicle at a parts supply sales location, at a repair facility or the like. For example, such testing may be desirable for an existing alternator motor before installing a new alternator. In the event that the existing alternator may pass the test, a user may eliminate that the alternator as the cause of a problem with the vehicle.

Alternator test equipment typically utilizes an AC motor as prime mover for rotating the alternator under test and the alternator is coupled to the prime mover through a belt for power transmission. During the test procedure, the prime mover rotates the alternator under test and applies known loads on the alternator, measures the output and checks the ability of the alternator to generate power at a particular current and voltage.

One of the assumptions during the test regarding the test equipment is that there is no loss or a minimum power transmission loss, which will not affect the test results of the alternator. This assumption is not valid and it may lead to failing a good alternator due to transmission belt slippage. In this regard, the drive belt may slip and accordingly not rotate the alternator as desired. This may result in an indication that the alternator is not properly functioning.

Thus, a need exists for determining whether the test equipment is properly operating before and/or during testing of the alternator so that the alternator function may be properly determined.

### SUMMARY

The foregoing needs are met, to a great extent, by the present disclosure, wherein in one aspect, an alternator tester that determines whether the alternator under test is being properly driven to ensure more accurate test results.

In an exemplary aspect, a diagnostic tool for testing the performance of a component of a vehicle is provided and can include a processor that can process test information from an alternator component of the vehicle and can control and activate the alternator component during an alternator test; a memory that can store the test information of the alternator component and software that can operate the alternator component of the vehicle, a motor having a pulley that can connect to the alternator, a first load component that can be controlled by the processor to put a first load on the alternator during testing, and an analog to digital converter (ADC) that can provide an output voltage of the alternator, wherein the processor determines a ripple frequency from the output voltage.

In another embodiment, a method of testing an alternator can include the steps of starting an alternator drive motor with a processor of an alternator tester, receiving a voltage output from an analog to digital converter with the processor, determining a first ripple frequency from the voltage output with the processor, determining a second ripple frequency after a first load is applied by a first load component that is controlled by the processor, calculating a first difference between the first and second ripple frequencies by the processor, and determining if the first difference exceeds a predetermined percentage by the processor.

In still another embodiment, a diagnostic tool for testing the performance of a component of a vehicle is provided and can include a processor that can process test information from an alternator component of the vehicle and can control and activate the alternator component during an alternator test, a memory that can store the test information of the alternator component and software that operates the alternator component of the vehicle, a motor that can drive the alternator during the test, a power supply that can supply power to the motor during testing, a first load component that can be controlled by the processor, wherein the first load can apply a first load on the alternator during testing, and an analog to digital converter (ADC) that can provide an output voltage of the alternator, wherein the processor determines a ripple frequency from the output voltage.

There has thus been outlined, rather broadly, certain aspects of the disclosure in order that the detailed description herein may be better understood, and in order that the present contribution to the art may be better appreciated. There are, of course, additional aspects of the present disclosure that will be described below and which will form the subject matter of the claims appended hereto.

In this respect, before explaining at least one aspect of the present disclosure in detail, it is to be understood that the present disclosure is not limited in its application to the details of construction and to the arrangements of the components set forth in the following description or illustrated in the drawings. The present disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the present disclosure. It is important, therefore, that the claims be regarded as including such equivalent constructions insofar as they do not depart from the spirit and scope of the present disclosure.

### BRIEF DESCRIPTION OF THE DRAWINGS

FIG. 1 is a perspective view of an alternator tester according to an aspect of the disclosure.

FIG. 2 is a perspective view of the alternator tester according to another exemplary aspect of the disclosure.

FIG. 3 is a block diagram of the components of the alternator tester depicted in FIGS. 1 and 2 according to an aspect of the disclosure.

FIG. 4 is a block diagram of the alternator test system with belt slip detection in accordance with an aspect of the disclosure.

FIG. 5 is a process flow diagram of the belt slip system in accordance with an aspect of the disclosure.

FIG. 6 is a schematic of the ripple frequency measurement device in accordance with an aspect of the disclosure.

### DETAILED DESCRIPTION OF EMBODIMENTS

The present disclosure will now be described with reference to the drawing figures, in which like reference numerals refer to like parts throughout. An aspect in accordance with the present disclosure provides an alternator tester for testing an alternator that includes a device for more accurate testing of the alternator of a motor vehicle engine or the like.

An aspect of the present testing apparatus is illustrated in FIG. 1. FIG. 1 illustrates an alternator motor tester 100 (“tester”) including a housing 112 and a base plate (or chassis) 114. The housing 112 surrounds and supports various operative components of the tester 100 including, for example, a power supply, diagnostic electronics, mounting devices, a monitor screen 123, a protective door cover 122, and the like. In one aspect, the monitor screen 123, e.g., LCD touch-screen may be disposed within the housing 112. A test power button 125, such as a toggle-switch, is provided on the housing 112 to activate and de-activate test power to the drive motor (not shown) and/or a transformer (not shown). A main power switch (not shown) may also be used to provide power to the tester 100.

The tester 100 also includes an alternator belt tensioning arrangement generally designated 116, an alternator mounting arrangement generally designated 118. The tester 100 may also include the ability to test a starter and may include a starter motor holder arrangement generally designated as 120. The belt tensioning arrangement 116 and the alternator mounting arrangement 118 may be mounted directly to the base plate 114.

The alternator belt tensioning arrangement 116 and the mounting arrangement 118 together hold the alternator in place for testing. An installation assembly that includes one or more mounting pins (not shown) can be placed in the mounting arrangement 118 in order to mount the alternator. The alternator can be horizontally or vertically mounted depending on the type of alternator. The pins are replaceable to allow flexibility for current and future applications.

Also shown in FIG. 1, a test adapter 126 and power leads 128 can be connected to the alternator in order to provide test information to the tester 100. Additionally, a drive belt (not shown), such as a serpentine or V belt or the like, can be connected to the alternator and the drive motor to simulate the operating environment in the vehicle. A gas piston may be used for belt tensioning to ensure consistent belt tension during testing, thereby eliminating over tensioning or belt slippage that may affect test results.

The starter motor holder arrangement 120 includes a quick release ratchet system, wherein the starter is placed on a pad and held in place by the ratchet system. The starter motor holder arrangement 120 includes, a support pad 130, a handle 132 and a release lock 134 that when operated engages and disengages a lock (pawl, for example) from a ratchet (both not shown). The starter motor holder arrangement 120 helps to eliminate the use of straps, and alternatively uses the quick ratchet to hold the starter without the need of any additional holding mechanism or end user assistance during the test. Thus, the aforementioned arrangement makes the loading and unloading of components to be tested much more efficient. The starter motor may be placed on the support pad 130 for testing. Upon the placement, the operator squeezes the release lock and presses down on the handle 132 to engage the starter motor and then releases the lock so that the lock is again reengaged. The starter motor may be powered by a transformer (not shown) in order to simulate operating environments. The transformer may be powered by an external power source and may provide test power to the starter motor via a heavy duty cable and clamps. Power leads 128, including, for example, battery lead, ground lead, solenoid lead and sense lead are connected to the starter motor in order to conduct the tests.

FIG. 1 also illustrates the monitor screen 123 that can operate as a touch-screen LCD user interface that communicates with a controller (discussed below) as well as to display information to the end user. The present disclosure also utilizes an on-line tutorial for quickly training new personnel on the unit's functionality and on-line help screens to help new users navigate and test components during a test. The monitor screen 123 may offer step-by-step instructions for setting up the tester 100 and conducting tests. The monitor screen 123 may also display on-screen hook up diagrams and a specification library database, which may eliminate the need for paper flipcharts and enables software updates for new alternator applications or starter configurations. This database can be updated by compact flash, flash drive, and other memory media or remotely via a network connection (discussed below). The monitor screen 123 may allow end users to run advertising screens when the tester is not in use. These screens can be uploaded to the tester 100 from an end user's network server or uploaded from a compact flash or other memory media. Additionally, the monitor screen 123 may be capable of displaying information in various updatable languages.

The tester 100 may output “Good/Bad” or “Pass/Fail” results to the end user. An end user printout that details test results and provides technical advice for other potential problems can be provided to the end user.

Turning now to FIG. 2, a perspective view of the alternator and starter motor tester 200 according to another exemplary aspect of the present disclosure is illustrated. The alternator and starter motor tester 200 (“tester”) has components similar to the tester 100 depicted in FIG. 1, however it has an alternative design. For example, tester 200 includes a housing 212 and a base plate (or chassis). The housing 212 surrounds and supports various operative components of the tester 200 including, for example, a power supply, diagnostic electronics, mounting devices, a monitor screen 223, a protective door cover 222, and the like. In the aspect depicted, the monitor screen 223, is an LCD touch-screen disposed within the housing 212. A power button 225, such as a toggle-switch design, is provided on the housing 212 to activate or deactivate test power to the driver motor (not shown) and/or the transformer (not shown). A main power switch (not shown) may also be used to provide power to the tester 200.

The tester 200 also includes an alternator belt tensioning arrangement generally designated 216, an alternator mounting arrangement generally designated, and a starter motor holder arrangement generally designated as 220. Each of the belt tensioning arrangement 216, the alternator mounting arrangement, and the starter motor holder arrangement 220 are mounted directly to the base plate (not shown).

The test adapters 226 and power leads 228 may be connected to the alternator or starter motor in order to provide test information to tester 200. Additionally, a drive belt (not shown), such as a serpentine or V belt or the like, can be connected to the alternator, the motor of the alternator and drive motor to simulate the operating environment in the vehicle. A gas piston may be used for belt tension to ensure consistent belt tension during testing and thereby eliminating over tensioning or slipping belts that may affect test results.

The starter motor holder arrangement 220 includes a quick release ratchet system, wherein the starter is placed on a pad and held in place by the ratchet system. The starter motor holder arrangement 220 includes, a support pad, a handle 232 and a release lock 234 that when operated engages and disengages a lock (pawl, for example) from a ratchet (both not shown). The starter motor holder arrangement 220 helps to eliminate the use of straps, and alternatively uses the quick ratchet to hold the starter without the need of any additional holding mechanism or end user assistance during the test. Thus, the aforementioned arrangement makes the loading and unloading of components to be tested much more efficient. The starter motor may be placed on the support pad for testing. Upon the arrangement, the operator squeezes the release lock and presses down on the handle 232 to engage the starter motor and then releases the lock so that the lock is again reengaged. Power leads 228, including, for example, battery lead, ground lead, solenoid lead and sense lead are connected to the starter motor in order to conduct the tests.

In the aspect depicted in FIG. 2, the tester 200 may incorporate enhanced safety features, such as the protective door cover 222 to enclose moving parts during tests. The protective door cover 222 conceals the belt tensioning arrangement 216, the alternator mounting arrangement, the starter motor holder arrangement 220, and other test components, such as an alternator or starter motor. The protective door cover 222 of the tester 200 is shown covering at least the belt tensioning arrangement 216, the alternator mounting arrangement, and the starter motor holder arrangement 220 when in the closed position.

In the closed position, the protective door cover 222 eliminates the possibility of hands getting caught in moving parts or projectiles potentially contacting the end user. The protective door cover 222 may employ a door interlock switch (not shown) to disable tests while the protective door cover 222 is open. Alternatively, the protective door cover 222 may include a viewing window so that the operator can observe the testing components during the tests.

FIG. 3 is a block diagram 300 of the components of the alternator and starter motor tester as previously described and shown in FIGS. 1 and 2 according to an exemplary aspect of the disclosure. The components generally include a monitor screen, such as LCD screen 302 that provides various information to the user. The LCD screen 302 may be a touch panel to input information as desired by the user and can be controlled by a processor 304. The processor 304 may be any processor or controller, including a FPGA (Field Programmable Gate Array). The processor 304 is capable running various OS (Operating System) including Linux, Apple Computer's Operating System (such as OS X), Windows, Windows CE and the like. The processor 304 communicates with a digital signal processor 306, which includes an analog and digital (ND) converter. The processor 304 communicates with other components (e.g., internal memory 308, USB port 312, RS-232 ports 316, motor 330, interface module 324 and/or diagnostic trouble code (DTC) interpreter 338) of the tester 100 via a communication bus 328.

The processor 304 is configured to communicate with an internal memory 308 and an external memory 310. The internal memory 308 and/or the external memory 310 can be any memory including, for example, compact flash, SD (secure digital), USB flash drives, and the like. A universal serial bus (USB) port 312 communicates with the processor 304 and provides a connection for various USB compatible devices, such as, for example, an external memory 310, a printer 314, a radio frequency identification (RFID) reader 332 and/or a diagnostic tool 336. The RFID reader 332 functions to read identifying information about the tested component containing an RFID chip once it is within a detection range. The RFID chip may contain information about the alternator or starter motor such as alternator/starter motor type, serial number, manufacturer, date of production or shipment, previous test results, electrical specifications, maintenance information, serial number, lot number, warranty information, a manufacture data code, method of shipment and the like.

The processor 304 also communicates with an interface module 324. The interface module 324 communicates with other external devices or external websites, such as a technical service bulletins (TSB) 334 through Internet 322. The interface module 324 includes a database (or access the internal memory 308 or the external memory 310 that stores the database) for storing information associated with the tested components and information associated with the diagnostic test performed by the tester 100. The RS-232 ports 316 also communicate with other external devices, such as a computing device 320, a bar code reader 318 and/or the diagnostic tool 336. In another exemplary aspect, the interface module 324 communicates with the technical service bulletins (TSB) 334 via the point-of-sale (POS) terminal 326. Further details of these components are described in U.S. patent application Ser. No. 13/463,292 filed May 3, 2012 and incorporated by reference herein in its entirety.

As described above, Alternator testers typically use a 120 VAC Motor to provide rotational drive to the alternator by means of a belt. Other configurations are contemplated as well. The drive capability of the motor to the alternator is largely dependent on the tension of the belt to prevent slippage under load. Without adequate belt tension, the belt can slip at either the driving pulley, on the motor, or at the driven pulley on the alternator, or both.

The alternator is designed to generate the proper DC voltage (typically 13.8 to 14.5 VDC) when driven over a range of RPM (revolutions per minute), typically about 800 to 10,000 RPM. If the alternator RPM slows to less than the low design RPM, the alternator's ability to generate the design voltage may not maintained. When the belt between the motor pulley and the alternator pulley is not fully tightened by the operator adequately, the belt can slip on one or both of the pulleys and the alternator RPM may drop below the design RPM, which will result in the Alternator output voltage being below the design voltage i.e., 13.8 v. Having this occur during the testing of the Alternator output would result in a failure decision of the Alternator Test. This “False” failure can cause the Alternator to be returned for warranty, thus incorrectly causing the cost of replacing the alternator. Additionally, it may cause the technician to incorrectly determine the cause of the problem in the power system. Therefore a “False” failure due to belt slip is highly undesirable.

The alternator is typically designed with inductive coils that create an alternating current (AC) voltage, which is rectified using diodes with each coil to produce a direct current (DC) voltage for charging the battery in a vehicle. The rectification by the diodes is not complete in that there is some level of ripple in the voltage after the rectification. The ripple frequency is generally directly proportional to the RPM of the alternator, the number of coils and/or diodes used in the specific design of the alternator.

This disclosure uses this ripple frequency proportional to the alternator RPM to determine if belt slip may be occurring. Belt slip when testing an alternator with the belt is not tightened sufficiently typically occurs when an electrical load is connected to the alternator output. This electrical load requires the alternator to produce more current in order to maintain the design output voltage. Producing more current requires more input power to the alternator pulley through the belt. The increase in power demand can cause belt slip.

When determining whether belt slip is occurring, the absolute (specific amount of RPM such as 655 rpm) RPM is not needed, because the RPM before the load is connected compared to the RPM after the load is connected can be analyzed for change. Specifically, if the RPM after the load is connected is significantly lower than the RPM before the load is connected, the reduced RPM is likely due to belt slip.

This disclosure measures the frequency of the voltage ripple on the output of the alternator, and converts it to a voltage related to the alternator RPM. Recording the frequency while the alternator is running (being driven by the motor through the belt) but without any electrical load as F(nl) (Frequency with no-load) and recording the frequency shortly after the electrical load is connected to the alternator as F(l1) (Frequency with load-one). The determination of whether the belt is slipping or not is determined by calculating the difference of the two frequencies; (Fnl−Fl1)=F(dif). Determining whether the frequency difference is larger than the expected amount that the motor may slow down due to the electrical load only, this can be described as X % of F(nl). If the frequency F(dif) is greater than frequency with no-load F(nl), times the percent of expected frequency slow down, it is highly likely there is belt slip occurring. With this condition the test can be stopped and the operator instructed to tighten the belt before starting the test again. This would prevent the cost of an alternator replacement under warranty on a “False” failure.

In other aspects, the belt slip check may be determined after a second heavier electrical load is connected. In this regard, it may be desirable to load the alternator with two separate loads. Having two separate loads allows a lighter load to be applied if the AC line voltage is low, and may be too low for the alternator tester to operate or trip a circuit breaker if the heavier load were applied. The belt slip procedure may be applied to analyze the RPM before and after the second load is connected, in the event that the belt slips only when the heavier load is applied.

FIG. 4 is a block diagram of the alternator test system with belt slip detection in accordance with an aspect of the disclosure. In particular, FIG. 4 shows a block diagram 400 of the alternator tester. The alternator 410 may be positioned in the alternator tester and connected with a belt 412 to the motor 330. The belt 412 may be connected to a pulley 408 of the alternator 410 and a pulley 406 of the motor 330.

The motor 330 may be driven by a 120 V alternating current power source 402. Other power sources are contemplated as well. The power source may be directly connected to the AC motor 330 or through a motor control 404. The motor control 404 may connect and disconnect the power from the power source 402 to the motor 330. More particularly, the motor control 404 may be a solenoid switch that is controlled by the processor 304. Other types of switches are contemplated as well.

After power from the power source 402 is provided to the AC motor 330 through a closed switch of the motor control 404, the motor 330 rotates and subsequently rotates the alternator 410. Rotating the alternator 410 will provide a power output from the B+ output of the alternator 410.

During this rotation of the alternator 410, the processor 304 or similar components may measure the ripple frequency of the power generated by the alternator 410 at described below in more detail. The alternator tester may further include an alternator load that may include a switch 414 that may be controlled by the processor 304 and a resistive load 416 that is grounded. This alternator load may cause the belt 412 to slip as described herein.

The alternator tester may further include a second load that includes a switch 418 that may be controlled by the processor 304 and a resistive load 420 that is grounded. This second alternator load may further cause the belt 412 to slip as described herein.

FIG. 5 is a process flow diagram of the belt slip system in accordance with an aspect of the disclosure. In particular, FIG. 5 shows an alternator test process 500. At 502 the alternator drive motor may be started by the application of power. Thereafter, the ripple frequency with no alternator load may be recorded at 504. Subsequently, at 506 the alternator control may be activated. Next, at step 508 a first load may be turned on, as described above, to provide a load to the alternator 410. Once this first load is applied to the alternator 410, the ripple frequency of the alternator is recorded at 510. Subsequently, the difference between the ripple frequency recorded at 504 and the ripple frequency recorded at 510 is determined at 512.

In 514, the difference between the two frequencies is determined, and is further determined whether or not it exceeds a particular percentage (X %) at 514. If it is determined in step 514 that the difference exceeds a particular percentage (yes), then the alternator test will be stopped at 516 and the technician instructed to tighten the belt and retest at 518.

On the other hand, if the difference does not exceed a particular percentage (no), the alternator test will continue at 520 and be completed at 522.

Additionally, the belt slip process 500 may further include a second load process 524. In this regard, after 520, the second load may be turned on at 526, the ripple frequency recorded at 528, and another difference calculation conducted at 530. In 532 the difference between the ripple frequency determined at 510 and the ripple frequency determined at 528 may be compared to determine whether or not the difference exceeds a particular percentage (X %). If the difference exceeds the percentage (yes), then the alternator test may be stopped at 534. Additionally, the technician may be instructed to tighten the belt and retest. On the other hand, if the difference does not exceed the predetermined percentage (no), the alternator test may be completed at 522.

FIG. 6 is a schematic of the ripple frequency measurement device in accordance with an aspect of the disclosure. In particular, FIG. 6 shows a circuit 600 that measures ripple frequency. The input of circuit 600 is at 602 that may be connected to the B+ output from the alternator. The output of circuit 600 is at 604 and includes an analog to digital converter. The analog to digital converter 604 generating a digital output of the ripple signal. The circuit 600 further includes capacitors 605, 606, 608, and 610; resistors 612, 614, 616, 618, 620, 622, and 624; op amps 626 and 628; and diodes 630 and 632 arranged as shown in FIG. 6. In operation, the input 602 receives the ripple voltage output from the alternator and counts the ripples that are generated as described above to provide a digital output at the analog-to-digital converter 604.

In further aspects, the frequency may be checked after motor is started to ensure alternator is running at a predetermined minimum RPM. In yet another aspect of the disclosure, the disclosure could be used to check for belt slip when the alternator is first started. Shortly after the motor is started to drive the alternator at a desired RPM, the alternator RPM may be checked to ensure that it has reached a minimum RPM. The minimum RPM would be predetermined and specified for each alternator. In this regard, a RPM specific to each alternator is required because for a motor with a specific design RPM and a motor pulley with a specific diameter, the alternator RPM may still be different due to the diameter size pulley it is designed with. In addition the frequency of the ripple is dependent on the number of coils and diodes in the specific alternator design, and is not the same for all alternators. So the alternator pulley diameter and the number of coils and diodes would need to be known for a minimum RPM. These parameters can be recorded with the part number for a specific alternator, and used to set variables in the Belt Slip algorithm to calculate the minimum RPM.

Further details of the alternator test process are described in U.S. patent application Ser. No. 13/463,292 filed May 3, 2012 and incorporated by reference herein in its entirety.

Accordingly, the disclosure as described herein determines whether the test equipment is properly operating before and/or during testing of the alternator so that the alternator function may be properly determined.

The disclosure may be implemented in any type of computing devices, such as, e.g., a desktop computer, personal computer, a laptop/mobile computer, a personal data assistant (PDA), a mobile phone, a tablet computer, cloud computing device, and the like, with wired/wireless communications capabilities via the communication channels.

Further in accordance with various embodiments of the disclosure, the methods described herein are intended for operation with dedicated hardware implementations including, but not limited to, PCs, PDAs, semiconductors, application specific integrated circuits (ASIC), programmable logic arrays, cloud computing devices, and other hardware devices constructed to implement the methods described herein.

It should also be noted that the software implementations of the disclosure as described herein are optionally stored on a tangible storage medium, such as: a magnetic medium such as a disk or tape; a magneto-optical or optical medium such as a disk; or a solid state medium such as a memory card or other package that houses one or more read-only (non-volatile) memories, random access memories, or other re-writable (volatile) memories. A digital file attachment to email or other self-contained information archive or set of archives is considered a distribution medium equivalent to a tangible storage medium. Accordingly, the disclosure is considered to include a tangible storage medium or distribution medium, as listed herein and including art-recognized equivalents and successor media, in which the software implementations herein are stored.

The many features and advantages of the present disclosure are apparent from the detailed specification, and thus, it is intended by the appended claims to cover all such features and advantages of the present disclosure, which fall within the true spirit, and scope of the present disclosure. Further, since numerous modifications and variations will readily occur to those skilled in the art, it is not desired to limit the present disclosure to the exact construction and operation illustrated and described, and accordingly, all suitable modifications and equivalents may be resorted to, falling within the scope of the present disclosure.

What is claimed is:

1. A diagnostic tool for testing the performance of a component of a vehicle, comprising:
a processor that processes test information from an alternator component of the vehicle and controls and activates the alternator component during an alternator test;
a memory that stores the test information of the alternator component and software that operates the alternator component of the vehicle;
a motor having a pulley that is connected to the alternator;
a first load component controlled by the processor to put a first load on the alternator during testing; and
an analog to digital converter (ADC) that provides an output voltage of the alternator, wherein the processor determines a ripple frequency from the output voltage.

2. The diagnostic tool according to claim 1, wherein the processor is configured to:
determine the ripple frequency before the first load is applied;
determine the ripple frequency after the first load is applied;
calculate a difference between the ripple frequencies before and after the first load is applied; and
determine if the first difference exceeds a predetermined percentage.

3. The diagnostic tool according to claim 2, wherein if the difference exceeds the predetermined percentage than the alternator test is stopped.

4. The diagnostic tool according to claim 2, wherein if the difference does not exceed the predetermined percentage than the alternator test is continued.

5. The diagnostic tool according to claim 1 further comprising:
a second load component controlled by the processor to put a second load on the alternator during testing.

6. The diagnostic tool according to claim 5, wherein the processor is configured to:
determine the ripple frequency after the first load is applied;
determine the ripple frequency after the second load is applied;
calculate the difference between the ripple frequencies of the first and second loads; and
determine if the difference exceeds a predetermined percentage.

7. The diagnostic tool according to claim 6, wherein if the difference exceeds the predetermined percentage than the alternator test is stopped.

8. The diagnostic tool according to claim 1 further comprising:
a display that displays information to a user; and
a radio frequency identification (RFID) reader that reads information from an RFID chip regarding the alternator.

9. A method of testing an alternator, comprising the steps of:
starting an alternator drive motor with a processor of an alternator tester;
receiving a voltage output from an analog to digital converter with the processor;
determining a first ripple frequency from the voltage output with the processor;
determining a second ripple frequency after a first load is applied by a first load component that is controlled by the processor;
calculating a first difference between the first and second ripple frequencies by the processor; and
determining if the first difference exceeds a predetermined percentage by the processor.

10. The testing method of claim 9, wherein if the first difference exceeds the predetermined percentage than the alternator test is stopped.

11. The testing method of claim 9, wherein if the first difference does not exceed the predetermined percentage than the alternator test is continued.

12. The testing method of claim 11 further comprising:
determining a third ripple frequency after a second load is applied by a second load component that is controlled by the processor;
calculating a second difference between the second and third ripple frequencies by the processor; and
determining if the second difference exceeds the predetermined percentage by the processor.

13. The testing method of claim 12, wherein if the second difference exceeds the predetermined percentage than the alternator test is stopped.

14. A diagnostic tool for testing the performance of a component of a vehicle, comprising:
a processor that processes test information from an alternator component of the vehicle and controls and activates the alternator component during an alternator test;
a memory that stores the test information of the alternator component and software that operates the alternator component of the vehicle;
a motor that drives the alternator during the test;
a power supply that supplies power to the motor during testing;
a first load component controlled by the processor, wherein the first load applies a first load on the alternator during testing; and
an analog to digital converter (ADC) that provides an output voltage of the alternator, wherein the processor determines a ripple frequency from the output voltage.

15. The diagnostic tool according to claim 14, wherein the processor is configured to:
determine the ripple frequency before the first load is applied;
determine the ripple frequency after the first load is applied;
calculate a difference between the ripple frequencies before and after the first load is applied; and
determine if the difference exceeds a predetermined percentage.

16. The diagnostic tool according to claim 15, wherein if the difference exceeds the predetermined percentage than the alternator test is stopped.

17. The diagnostic tool according to claim 15, wherein if the difference does not exceed the predetermined percentage than the alternator test is continued.

18. The diagnostic tool according to claim 14 further comprising:
a second load component controlled by the processor to put a second load on the alternator during testing.

19. The diagnostic tool according to claim 14, wherein the processor is configured to:
determine the ripple frequency after the first load is applied;
determine the ripple frequency after the second load is applied;
calculate the difference between the ripple frequencies of the first and second loads; and
determine if the difference exceeds a predetermined percentage.

20. The diagnostic tool according to claim 19, wherein if the difference exceeds the predetermined percentage than the alternator test is stopped.
